(19) United States
(12) Patent Application Publication
(10) Pub. No.: US 2016/0322965 A1
(43) Pub. Date: Nov. 3, 2016

(54) DIFFERENTIAL COMPARATOR WITH STABLE OFFSET

(71) Applicant: SanDisk Technologies Inc., Plano, TX (US)

(72) Inventors: Tomer Elran, Petah Tikva (IL); Ilan Wienner, Herzliya (IL)

(21) Appl. No.: 14/701,080

(22) Filed: Apr. 30, 2015

(51) Int. Cl. H03K 5/24; H03K 17/687

(52) U.S. Cl. CPC H03K 5/24; H03K 17/687

(57) ABSTRACT

A comparator system may include a comparator circuit and input circuitry coupled to a communication line. The circuitry may include resistors that are used to generate input voltages supplied to input terminals of the comparator. Resistor-dependent currents generated from a resistor-dependent current source may be supplied to the resistors of the input circuitry. The resistors of the input circuitry and resistors of the resistor-dependent current source may be of the same type and/or configured on the same chip to increase stability in the presence of various process-voltage-temperature (PVT) conditions. The comparator system may be implemented as a squelch detector or other signal detection system, such that an output generated by the comparator based on the input voltages may indicate presence or absence of a signal.

### BACKGROUND

Squelch detectors may be used with communication links to provide an indication of whether a signal is present on a link or communication line. Some squelch detectors may provide the indication based on a voltage difference between two signals. However, if the voltage difference that is generated is not stable due to instability-causing factors such as temperature changes or noise, the indication provided by squelch detector may be false. As such, it may be desirable to generate a voltage difference that is stable in the presence of instability-causing factors so that the output provided by the squelch detector is accurate.

### BRIEF DESCRIPTION OF THE DRAWINGS

FIG. 1 is a circuit schematic diagram of an example differential comparator system.

FIG. 2 is a circuit schematic diagram of another example differential comparator system.

FIG. 3 is a circuit schematic diagram of an example resistor-dependent current source.

FIG. 4 is a circuit schematic diagram of another example resistor-dependent current source.

FIG. 5 is a flow chart of an example method of detecting a signal communicated on a communication line.

### DETAILED DESCRIPTION OF THE PRESENTLY PREFERRED EMBODIMENTS

### Overview

By way of introduction, the below embodiments relate to electronic systems and related methods for providing an accurate, stable, and configurable offset across a wide range of fabrication process, voltage, and temperature conditions. In one embodiment, a comparator system may include a comparator circuit, an input circuit, and a resistor-dependent current generation circuit. The comparator circuit may be configured to receive a first input voltage and a second input voltage, and output an output voltage based on a difference between the first input voltage and the second input voltage. The input circuit may include first resistor circuitry and be circuit configured to: generate the first input voltage based on the first resistor circuitry, and supply the first input voltage to the comparator circuit. The resistor-dependent current generation circuit may include second resistor circuitry and be configured to generate a resistor-dependent current that depends on the second resistor circuitry, and supply the resistor-dependent current to the first resistor circuitry to generate the first input voltage. The first resistor circuitry and the second resistor circuitry may be of the same type.

In another embodiment, a signal detection system may include a signal detection circuit coupled to a pair of communication lines. The signal detection circuit may include first resistor circuitry, a comparator circuit, and a resistor-dependent generation circuit. The first resistor circuitry may be configured to generate an offset voltage. A comparator circuit may be coupled to the first resistor circuitry and be configured to generate an output voltage at a level that indicates whether a first line voltage on the pair of communication lines exceeds a second line voltage on the pair of communication lines by an amount corresponding to the offset voltage. The resistor-dependent current generation circuit may include second resistor circuitry and be configured to generate a resistor-dependent current that depends on the second resistor circuitry, and supply the resistor-dependent current to the first resistor circuitry to generate the offset voltage. The first resistor circuitry and the second resistor circuitry may be of the same type.

In yet another embodiment, a method of detecting presence of a signal on a pair of communication lines may be performed. The method may include generating, with resistor-dependent current generation circuitry, a resistor-dependent current that depends on first resistor circuitry; and generating, with second resistor circuitry, an offset voltage in response to the resistor-dependent current. In addition, the method may include generating, with a first input circuit coupled to the pair of communication lines, a first input voltage at a first input terminal of a comparator circuit, where the first input voltage is based on the offset voltage and a first line voltage generated on the pair of communication lines; and generating, with a second input circuit coupled to the pair of communication lines, a second input voltage at a second input terminal of the comparator circuit, where the second input voltage based on a second line voltage generated on the pair of communication lines. The method may also include outputting, with the comparator circuit, an output voltage based on a difference between the first input voltage and the second input voltage, where a level of the output voltage indicates presence or absence of a signal being communicated on the pair of communication lines.

In some embodiments, the input circuit and the resistor-dependent current generation circuit may be configured on the same chip.

In some embodiments, the resistor-dependent current generation circuitry may include a current source circuit and a current mirror circuit. The current source circuit may include the second resistor circuitry and be configured to generate a reference current that depends on the second resistor circuitry. The current mirror circuit may be configured to mirror the reference current to generate the resistor-dependent current, and supply the resistor-dependent current to the first resistor circuitry.

In some embodiments, a switch may be connected in parallel with the first resistor circuitry, and a feedback connection may couple an output terminal of the comparator circuit with the switch, where a level of the output voltage controls switching of the switch.

In some embodiments, the first resistor circuitry and the second resistor circuitry may have respective temperature coefficient parameters that are within 5% of each other.

In some embodiments, the first resistor circuitry and the second resistor circuitry may be both polysilicon resistors, P-POLY resistors saliside, P-POLY resistors non-saliside, N-POLY resistors saliside, N-POLY resistors non-saliside, Nwell resistors, or metal resistors.

Other embodiments may be possible, and each of the embodiments can be used alone or together in combination. Accordingly, various embodiments will now be described with reference to the attached drawings.

### Exemplary Embodiments

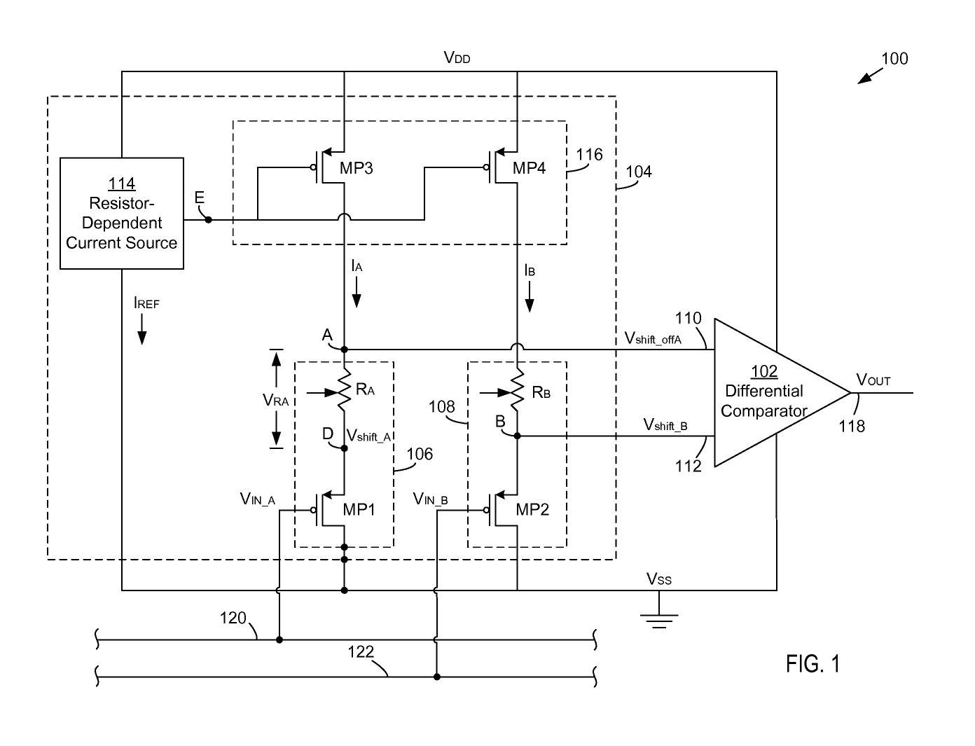

The following embodiments can be used to provide an accurate, stable, and configurable offset across a wide range of fabrication process, voltage, and temperature (PVT) conditions. FIG. 1 is a circuit schematic diagram of an example differential comparator system 100. The differential comparator system 100 may include a differential comparator circuit 102 and comparator input circuitry 104 configured to generate and supply a pair of comparator input voltages, including a first comparator input voltage V_{shift}_{_}_{offA} and a second comparator input voltage V_{shift}_{_}_{B}, to the differential comparator circuit 102. The differential comparator circuit 102 may be configured to generate and output an output voltage V_{OUT} at an output terminal 118 based on a difference of the first comparator input voltage V_{shift}_{_}_{offA} and the second comparator input voltage V_{shift}_{_}_{B}. In particular, the differential comparator circuit 102 may generate the output voltage V_{OUT} at a level that indicates which of the first comparator input voltage V_{shift}_{_}_{offA} and the second comparator input voltage V_{shift}_{_}_{B} is higher than the other. That is, the differential comparator circuit 102 may generate the output voltage V_{OUT} at a first level if the first comparator input voltage V_{shift}_{_}_{offA} is higher than the second comparator input voltage V_{shift}_{_}_{B}, and may generate the output voltage V_{OUT} at a second level if the second comparator input voltage V_{shift}_{_}_{B} is higher than the first comparator input voltage V_{shift}_{_}_{offA}.

The comparator input circuitry 104 may be configured to receive a pair of input voltages, including a first input voltage V_{IN}_{_}_{A} and a second input voltage V_{IN}_{_}_{B}, and generate the pair of comparator input voltages V_{shift}_{_}_{offA}, V_{shift}_{_}_{B} based on the pair of input voltages V_{IN}_{_}_{A}, V_{IN}_{_}_{B}. The comparator input circuitry 104 may include a first input circuit 106 and a second input circuit 108. The first input circuit 106 may include first resistor circuitry R_{A} connected in series with a first transistor MP2. The first resistor circuitry R_{A} may include a potentiometer, although other circuits or circuit configurations that provide a resistance, including a programmable and/or a reconfigurable resistance, may be possible. Additionally, as shown in FIG. 1, the first transistor MP1 may be a p-channel metal-oxide-semiconductor field-effect transistor (PMOS transistor), although other types of transistor or switching circuitry may be possible. The PMOS transistor MP1 may have a gate terminal configured to receive the first input voltage V_{IN}_{_}_{A}. Additionally, the first PMOS transistor MP1 may have a source terminal connected to a first end of the first resistor circuitry R_{A} at a node D, and a drain terminal connected to a ground reference voltage V_{SS}. A second end of the first resistor circuitry R_{A} may be connected to a first input terminal 110 of the differential comparator circuit 102 at a node A at which the first comparator input voltage V_{shift}_{_}_{offA} may be generated. Accordingly, the first comparator input voltage V_{shift}_{_}_{offA} generated at node A with respect to ground may be the sum of a first resistor voltage generated across the first resistor circuitry R_{A} and a source-to-drain voltage generated across the source and drain terminals of the first PMOS transistor MP1. The source-to-drain voltage, and in turn the first comparator input voltage V_{shift}_{_}_{offA}, may depend on the level of the first input voltage V_{IN}_{_}_{A} applied to the gate terminal of the first PMOS transistor MP1.

The second input circuitry 108 may include second resistor circuitry R_{B} connected in series with a second transistor MP2. Like the first input circuitry 106, the second resistor circuitry R_{B} may include a potentiometer and the second transistor MP2 may be a PMOS transistor, although other types of resistance-providing circuitry and/or switching circuitry may be possible. The second PMOS transistor MP2 may have a gate terminal configured to receive the second input voltage V_{IN}_{_}_{B}. Additionally, the second PMOS transistor MP2 may have a source terminal connected to a first end of the second resistor circuitry R_{B} at a node B, and a drain terminal connected to the ground reference voltage V_{SS}. The second comparator input voltage V_{shift}_{_}_{B} may be generated at node B, which may be connected to a second input terminal 112 of the differential comparator circuit 102. The second comparator input voltage V_{shift}_{_}_{B} generated at node B with respect to ground may be a source-to-drain voltage generated across the source and drain terminals of the second PMOS transistor MP2, which may depend on the level of the second input voltage V_{IN}_{_}_{B} applied to the gate terminal of the second PMOS transistor MP2.

The comparator input circuitry 104 my further include current generation circuitry configured to generate and provide currents to each of the first input circuitry 106 and the second input circuitry 108. The current generation circuitry may include a resistor-dependent current source 114 that is configured to generate a reference current I_{REF}, which may be a direct current (DC) current source that is dependent upon a resistance of the resistance-dependent current source 114. The resistance may be a single resistance provided by a single resistor or a plurality of resistances provided by a plurality of resistors. An amount of the reference current I_{REF} generated by the resistor-dependent current source 114 may depend on and/or be determined by the resistance of the resistor-dependent current source 114. Accordingly, changes in the resistance of the resistor-dependent current source 114 may cause a change in the amount of the reference current I_{REF} that is generated. For some example configurations, there may be an inverse relationship between the resistance of the resistor-dependent current source 114 and the amount of the reference current I_{REF} that is generated. For example, an increase in the resistance may cause a decrease in the amount of the reference current I_{REF}, and vice versa.

As described in further detail below, the resistors of the resistor-dependent current source 114 may be of the same type or kind as each other as well the same type or kind as the resistors of the first resistor circuitry R_{A} and the second resistor circuitry R_{B}. Resistors of the same type or kind may be made of the same material, have the same size, or combinations thereof. As non-limiting examples, the resistors of the resistor-dependent current source 114 and the first and second resistor circuitries R_{A}, R_{B} may each be polysilicon resistors, P-POLY resistors saliside, P-POLY resistors non-saliside, N-POLY resistors saliside, N-POLY resistors non-saliside, Nwell resistors, or metal resistors.

In addition or alternatively, the resistors of the resistor-dependent current source 114 and the first and second resistor circuitries R_{A}, R_{B} may be of the same type in that they respond to and/or are affected by one or more process-voltage-temperature (PVT) conditions in the same or similar ways. That is, their respective resistances may respond or vary in the same way or proportional to each other when subjected to the same PVT conditions and/or changes in PCT conditions. One example PVT condition may include temperature (e.g., environmental or surrounding temperature. By being of the same type, the respective resistances of the resistors of the resistor-dependent current source 114 and the first and second resistor circuitries R_{A}, R_{B} may have the same or similar temperature coefficient parameters (e.g., within 5% of each other) that indicate how a resistor may response to temperature variation. As a result, the respective resistances of the resistors of the resistor-dependent current source 114 and the first and second resistor circuitries R_{A}, R_{B} may change or otherwise respond in the same way or proportional to each other when subjected to a change in temperature of the surrounding environment. Another PVT condition may include process variations.

In addition, for some example configurations, at least the resistor-dependent current source 114 and the first and second resistor circuitries R_{A}, R_{B} may be configured on the same or a single chip or integrated circuit (IC). In particular example configurations, the circuit components of the comparator input circuitry 104; the components of the comparator circuitry 104 and the differential comparator circuit 102; and/or the differential comparator system 100 as a whole may be configured on the same chip or IC. In addition to temperature, another example PVT condition may be process variation. Due to imperfections in fabrication processes, an actual resistance of a resistor may be different that its target or designed-for resistance. Such differences may be referred to as resistance drift or mismatch. However, resistance drift may be much lower among resistors located on the same chip or IC (e.g., less than 1%), compared to resistance drift among resistors located on different chips or ICs (e.g., 5-6%). As such, by being located on the same chip or IC, the resistors of the resistor-dependent current source 114 and the first and second resistor circuitries R_{A}, R_{B} may have the same or very similar (e.g., less than 1%) resistance drifts.

The current generation circuitry may further include current mirror circuitry 116 that is configured to mirror the reference current I_{REF} generated by the resistor-dependent current source 114 to generate a first mirrored current I_{A} and a second mirrored current I_{B}. As shown in FIG. 1, the current mirror circuitry 116 may include a third PMOS transistor MP3 that generates the first mirrored current I_{A} and supplies the first mirrored current I_{A} to the first input circuitry 106, and a fourth PMOS transistor MP4 that generates the second mirrored current I_{B} and supplies the second mirrored current I_{B} to the second input circuitry 108. The third PMOS transistor MP3 may have a source terminal coupled to a supply voltage V_{DD} and a drain terminal coupled to the second end of the first resistor circuitry R_{A} at node A at which the first comparator input voltage V_{shift}_{_}_{offA} is generated. In addition, the fourth PMOS transistor MP4 may have a source terminal coupled to the supply voltage V_{DD} and a drain terminal coupled to a second end of the second resistor circuitry R_{B}. Also, in order to mirror the reference current I_{REF}, gate terminals of the third and fourth PMOS transistor MP3, MP4 may each be connected at a node E to a gate terminal of a transistor of the resistor-dependent current source 114 generating the reference current I_{REF}, as described in further detail below. By being mirrored versions of the reference current I_{REF}, each of the first mirrored current I_{A} and the second mirrored current I_{B} may have amounts that are the same as and/or proportional to the amount of the reference current I_{REF}, depending on the respective sizes of the third and fourth PMOS transistors MP3, MP4 in relation to the size of the transistor of the resistor-dependent current source 114 generating the reference current I_{REF}.

For some example configurations, the third and fourth PMOS transistors MP3 and MP4 may have the same or substantially the same sizes as each other so that the amounts of first and second mirrored currents I_{A} and I_{B} are the same or substantially the same as each other. Additionally, the resistances of the resistor circuities R_{A} and R_{B} may be the same or substantially the same. As a result, the voltages generated across the resistor circuitries R_{A} and R_{B} may be the same or substantially the same as each other.

Further, the level of the voltage V_{shift A} generated at node D may be above or shifted up from the level of the first input voltage V_{IN}_{_}_{A}. Similarly, the level of the voltage V_{shift}_{_}_{B} generated at node B may be above or shifted up from the level of the first input voltage V_{IN}_{_}_{B}. In a particular example configuration, the first and second PMOS transistors MP1 and MP2 may be sized, and the amount of the first and second mirrored currents I_{A} and I_{B} may be generated such that the amounts that the voltages V_{shift}_{_}_{A} and V_{shift}_{_}_{B} are shifted up may be the threshold voltage V_{T} of the first and second PMOS transistors MP1 and MP2.

Additionally, for particular implementations, the first and second input voltages V_{IN}_{_}_{A} and V_{IN}_{_}_{B} may be low enough such that the first and second PMOS transistors MP1 and MP2 remain turned on for varying levels of the first and second input voltages V_{IN}_{_}_{A} and V_{IN}_{_}_{B}. Also, the levels of the voltages V_{shift}_{_}_{A} and V_{shift}_{_}_{B} may vary linearly in proportion to the varying levels of the first and second input voltages V_{IN}_{_}_{A} and V_{IN}_{_}_{B}. The first and second PMOS transistors may have the same or substantially the same size so that when the first and second input voltage V_{IN}_{_}_{A} and V_{IN}_{_}_{B} are at the same level, the voltages V_{shift}_{_}_{A} and V_{shift}_{_}_{B} may also be at the same level. As such, when the first and second input voltage V_{IN}_{_}_{A} and V_{IN}_{_}_{B} are at the same level, the difference between the first comparator input voltage V_{shift}_{_}_{offA} and the second comparator input voltage V_{shift}_{_}_{B} may be the voltage generated across the first resistors circuitry R_{A}, hereafter referred to as the first resistor voltage V_{RA}. For some applications, the first resistor voltage V_{RA} may be an offset voltage indicative of an amount that the first comparator input voltage V_{shift}_{_}_{offA} is offset from the second comparator input voltage V_{shiftB}.

In operation, as long as the difference between the first input voltage V_{IN}_{_}_{A} and the second input voltage V_{IN}_{_}_{B} is less than the first resistor voltage V_{RA} (e.g., the offset voltage) the differential comparator circuit 102 may output the voltage V_{OUT} at a level that indicates that the first comparator input voltage V_{shift}_{_}_{offA} is greater than the second comparator input voltage V_{shift}_{_}_{B}. However, when the second input voltage V_{IN}_{_}_{B} increases above the first input voltage V_{IN}_{_}_{A} by an amount that is greater than or equal to the first resistor voltage V_{RA}, the level of the second comparator input voltage V_{shift}_{_}_{B} may be correspondingly greater than or equal to the level of the first comparator input voltage V_{shift}_{_}_{offA}. When this occurs, the level of the output voltage V_{OUT} may change to indicate that the level of the second comparator input voltage V_{shift}_{_}_{B} is greater than or equal to the level of the first comparator input voltage V_{shift}_{_}_{offA}. Subsequently, if the level of the second input voltage V_{IN}_{_}_{B} falls below the first resistor voltage V_{RA}, the first comparator input voltage V_{shift}_{_}_{offA} may again be correspondingly above the second comparator input voltage V_{shift}_{_}_{offA}, and the level of the output voltage V_{OUT} may switch back to indicate that relationship.

For some example configurations, the differential comparator system 100 may be implemented as a squelch detector or other signal detection circuit or system that detects a presence or absence of a signal being communicated on a link or communication line. The signal being communicated may be a data signal, a command signal, or other type of signal that may be differentiated from noise. Accordingly, for purposes of the present description, the term “signal” includes any signal carrying data or any other information other than or in addition to noise.

FIG. 1 shows the gate terminal of the first PMOS transistor MP1 coupled to a first communication line 120 such that the first input voltage V_{IN}_{_}_{A} is proportional to a line voltage being generated on the first communication line 120. Similarly, the gate terminal of the second PMOS transistor MP2 may be coupled to a second communication line 122 such that the second input voltage V_{IN}_{_}_{B} is proportional to a line voltage being generated on the second communication line 122. When implemented as a squelch detector or other signal detection circuit, the differential comparator system 100 may be configured to detect presence or absence of a signal being communicated on one or both of the communication lines.

In some example implementations, the signal being communicated on the communication lines 120, 122 may be a differential signal. When no differential signal is being communicated, only noise may be present on the lines 120, 122, and any difference in the voltages generated on the lines 120, 122 from the noise may be small enough (i.e., less the first resistor voltage V_{RA}) such that the resulting first comparator input voltage V_{shift}_{_}_{offA} may be greater than the second comparator input voltage V_{shiftB}. As a result, the level of the output signal V_{OUT} generated by the differential comparator circuit 102 when the first comparator input voltage V_{shift}_{_}_{offA} is greater than the second comparator input voltage V_{shiftB} may indicate that no signal is being communicated on the differential communication lines 120, 122. Alternatively, when a differential signal is being communicated, there may be a time during the communication when a voltage of a signal of the differential pair being communicated on the second communication line 122 may be the same as or exceed a voltage of the other signal of the differential pair being communicated on the first communication line 120 by an amount corresponding to the first resistor voltage V_{RA}. When this occurs, the level of the second comparator input signal V_{shift}_{_}_{B} may be greater than or equal to the level of the first comparator input voltage V_{shift}_{_}_{offA}. As a result, the differential comparator circuit 102 may output the output voltage V_{OUT} at a level indicate the presence of a signal being communicated on the communication lines 120, 122. Subsequently, when communication of the differential signal stops such that there is only noise on the lines 120, 122, the level of the second comparator input voltage V_{shift}_{_}_{B} may again fall below the level of the first comparator input voltage V_{shift}_{_}_{offA}, and in turn, the differential comparator circuit 102 may again output the output voltage V_{OUT} at a level to indicate that no signal is being communicated on the lines 120, 122.

In other example implementations, the first communication line 120 may be configured to communicate a reference voltage, and the second communication line 122 may be configured to communicate a signal (either a single-ended signal or a signal of a differential pair). When no signal is being communicated on the second communication line 122, any voltage level generated as a result of noise generated on the second line 122 relative to the reference voltage generated on the first line 120 may be less than the first resistor voltage V_{RA}. As a result, the first comparator input voltage V_{shift}_{_}_{offA} may be greater than the second comparator input voltage V_{shift}_{_}_{B}, and in turn the differential comparator circuit 102 may output the output voltage V_{OUT} at a level that indicates that no signal is being communicated on the second line 122. Alternatively, when a signal is communicated on the second communication line 122, the voltage level on the second line 122 relative to the reference voltage generated on the first line 120 may be greater than or equal to first resistor voltage V_{RA} such that the differential comparator circuit 102 outputs the output voltage V_{OUT} at a level that indicates a signal is being communicated on the second communication line 122.

For the example differential comparator system 100, if the level of the signal being communicated is relatively small such that the level of the second comparator input voltage V_{shift}_{_}_{B} exceeds the level of the first comparator input voltage V_{shift}_{_}_{offA} by only a small amount, then fluctuations in the signal level may cause the level of the second comparator input voltage V_{shift}_{_}_{B} to fall below the level of the first comparator input voltage V_{shift}_{_}_{offA} which in turn may cause the differential comparator circuit 102 may output the output voltage V_{OUT} at the level indicating that no signal is being communicated even though one still is. To avoid such incorrect indications, the differential comparator system 100 may be modified to include hysteretic functionality such that after the second comparator input voltage V_{shift}_{_}_{B} increases above the first comparator input voltage V_{shift}_{_}_{offA}, the level of the first comparator input voltage V_{shift}_{_}_{offA} drops to increase the amount that level of the second comparator input voltage V_{shift}_{_}_{B} has to drop in order to fall back below the level of the first comparator input voltage V_{shift}_{_}_{offA}.

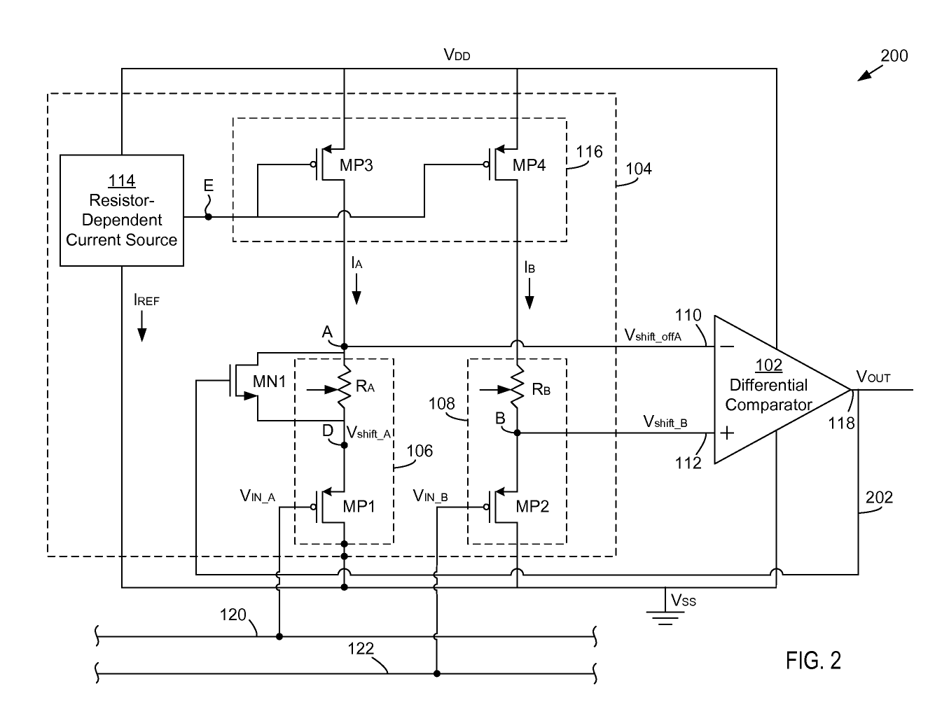

FIG. 2 is a circuit schematic diagram of another example differential comparator system 200 that has the hysteretic functionality. The differential comparator system 200 is similar to the differential comparator system 100 except that the differential comparator system 200 further includes a p-channel metal-oxide-semiconductor field-effect transistor (PMOS transistor) MN1 connected in parallel with the first resistor circuitry R_{A}, and a feedback connection 202 that connects the output terminal 118 of the differential comparator circuit with a gate terminal of the NMOS transistor.

The input terminals 110 and 112 of the differential comparator circuit 102 may be configured such that the first input terminal 110 configured to receive the first comparator input voltage V_{shift}_{_}_{offA} may be the negative input terminal and the second input terminal 112 configured to receive the second comparator input voltage V_{shift}_{_}_{B} may be the positive input terminal. As such, when the first comparator input voltage V_{shift}_{_}_{off} is higher than the second comparator input voltage V_{shift}_{_}_{B}, the differential comparator circuit 102 may generate the output voltage V_{OUT} at a low level. This low level, applied to the gate terminal of the NMOS transistor MN1 via the feedback connection 202, may turn off the NMOS transistor MN1 such that NMOS transistor MN1 has a relatively high resistance, functioning substantially as an open circuit. Accordingly, all or substantially all of the first mirrored current I_{A} may flow through the first resistor circuitry R_{A} instead of the NMOS transistor MN1. Alternatively, when the second comparator input voltage V_{shift}_{_}_{B} rises above the first comparator input voltage V_{shift}_{_}_{offA}, the differential comparator circuit 102 may generate the output voltage V_{OUT} at a high level. This high level, applied to the gate terminal of the NMOS transistor MN1 via the feedback connection 202, may turn on the NMOS transistor MN1 such that the NMOS transistor MN1 has a relatively low resistance, functioning substantially as a short circuit. Accordingly, most if not all of the first mirrored current I_{A} may flow through the NMOS transistor MN1 instead of through the first resistor circuitry R_{A}.

When the NMOS transistor MN1 is turned off, the first comparator input voltage V_{shift}_{_}_{offA} generated at node A may be at or substantially at the level at which it was generated in the first example differential comparator system 100 of FIG. 1. Accordingly, for the second comparator input voltage V_{shift}_{_}_{B} to rise above the first comparator input voltage V_{shift}_{_}_{offA}, the second input voltage V_{IN}_{_}_{B} may correspondingly rise above the first input voltage V_{IN}_{_}_{A} by an amount greater than the voltage generated across the first resistor circuitry R_{A}. However, when the second comparator input voltage V_{shift}_{_}_{B} does rise above the first comparator input voltage V_{shift}_{_}_{offA}, the high level of the output voltage V_{OUT} may turn on the NMOS transistor MN1, causing the first comparator input voltage V_{shift}_{_}_{offA} generated at node A to drop to a level slightly above the level of the voltage V_{shift}_{_}_{A} generated at node D. As a result, the second comparator input voltage V_{shift}_{_}_{B}, and correspondingly the second input voltage V_{IN}_{_}_{B}, has to fall by a greater amount to be below the level of the first comparator input voltage V_{shift}_{_}_{offA} than if the first comparator input voltage V_{shift}_{_}_{offA} remained at its initial level.

For squelch detector or other signal detection applications, such a hysteretic feature may provide for more accurate signal detection in that the voltage generated on the second communication line 122 has to fall a greater amount than the amount that the second comparator voltage V_{shift}_{_}_{B} increased above the first comparator input voltage V_{shift}_{_}_{A} to initially cause the differential comparator circuit 102 to indicate a presence of a signal. To illustrate, suppose that prior to detection of a signal, the first comparator input voltage V_{shift}_{_}_{offA} generated at node A is 250 mV and the level of the voltage V_{shift}_{_}_{A} generated at node A is 200 mV. In other words, the first resistor voltage V_{RA} is 50 mV. Subsequently, suppose a differential signal is communicated on the lines 120, 122, causing the second comparator voltage V_{shift}_{_}_{B} to increase to 255 mV, or 5 mV above the first comparator input voltage V_{shift}_{_}_{offA}. Referring to the first differential comparator system 100, if that signal being communicated has a voltage that fluctuates around 5 mV, the second comparator input voltage V_{shift}_{_}_{B} may drop below the first comparator input voltage V_{shift}_{_}_{offA} of 250 mV, causing the differential comparator circuit 102 to output the output voltage V_{OUT} to indicate that a signal is no longer being communicated on the lines 120, 122. Alternatively, referring to the second differential comparator system 200, when the second comparator input signal V_{shift}_{_}_{B} rises to 255 mV, the differential comparator circuit 102 outputs the output voltage V_{OUT} at a high level, causing the NMOS transistor MN1 to turn on. By turning on, the NMOS transistor MN1 may cause the voltage drop from node A to node D to be only a couple millivolts, such as 2 mV for example. Accordingly, the first comparator input voltage V_{shift}_{_}_{offA} may drop from 250 mV to 202 mV. In turn, the second comparator input voltage V_{shift}_{_}_{B} may have to fall below 202 mV instead of only 250 mV (i.e., 48 more millivolts) in order to cause the differential comparator circuit 102 to output the output voltage V_{OUT} at a level that indicates no signal is being communicated. As a result, small fluctuations in the voltage of the signal being communicated on the signal lines 120, 122 may prevent an incorrect indication provided by the differential comparator circuit 102.

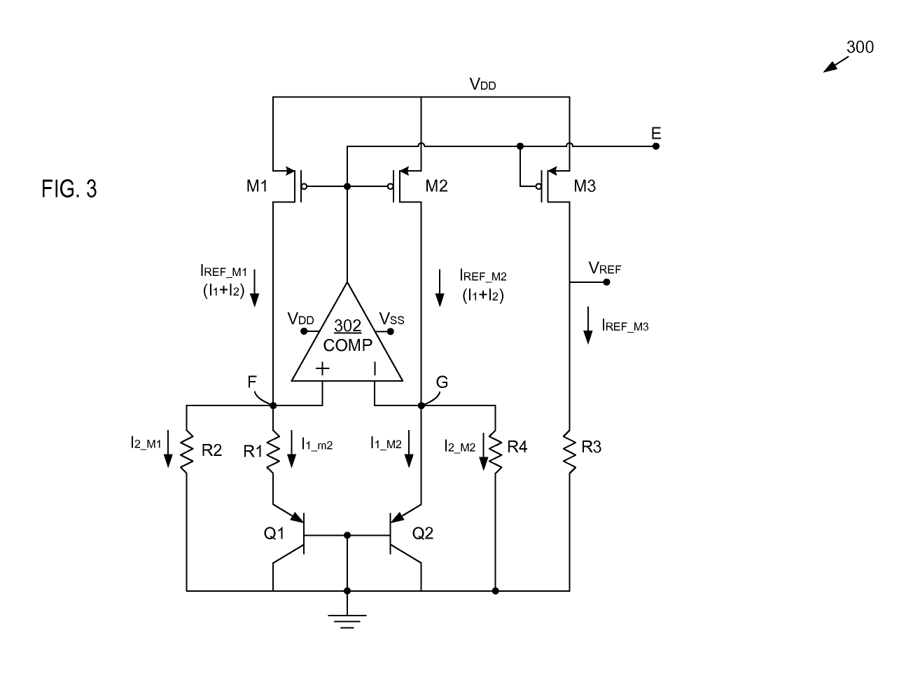

FIG. 3 shows a circuit schematic diagram of an example resistor-dependent current source 300, which may be used for the resistor-dependent current source 114 of the example differential comparator systems 100 and 200. The resistor-dependent current source 300 may include a plurality of PMOS transistors, including a first PMOS transistor M1, a second PMOS transistor M2, and a third PMOS transistor M3. Source terminals of each of the PMOS transistors M1, M2, M3 may be connected to the supply voltage V_{DD}. In addition, gate terminals of each of the PMOS transistors M1, M2, M3 may be connected to each other and to an output of an analog comparator circuit 302. A drain terminal of the first PMOS transistor M1, a first end of a first resistor R1 and a first end of a second resistor R2 may be connected to a positive input terminal of the analog comparator circuit 302 at a node F. A second end of the first resistor R1 may be connected to an emitter terminal of a first bipolar junction transistor (BJT) Q1. Each of a collector terminal of the first BJT Q1 and a second end of the second resistor R2 may be connected to the ground reference voltage V_{SS}. A drain terminal of the second PMOS transistor M2, an emitter terminal of a second BJT Q2 and a first end of a fourth resistor R4 may be connected to a negative input terminal of the analog comparator circuit 302 at a node G. Each of a collector terminal of the second BJT Q2 and a second end of the fourth resistor R4 may be connected to the ground reference voltage V_{SS}. Additionally, base terminals of the first and second BJTs Q1, Q2 may be tied together and also connected to the ground reference voltage V_{SS}. In addition, as shown in FIG. 3, a drain terminal of the third PMOS transistor M3 may be connected to a first end of a third resistor R3, and a second end of the third resistor R3 may be connected to the ground reference voltage V_{SS}.

The analog comparator circuit 302 may output an output voltage indicative of the difference between the voltages generated at nodes F and G, and that output voltage may be applied to the gate terminals of the PMOS transistors M1, M2, M3. In response, reference currents I_{REF}_{_}_{M1}, I_{REF}_{_}_{M2}, I_{REF}_{_}_{M3} may flow through first, second, and third PMOS transistors M1, M2, M3, respectively. The reference currents I_{REF}_{_}_{M1}, I_{REF}_{_}_{M2}, I_{REF}_{_}_{M3} may mirrored versions of each other and equal and/or proportional in amount to each other. At node F, a first portion I₁_{_}_{M1} of reference current I_{REF}_{_}_{M1} may flow through the first resistor and the first BJT Q2, and a second portion I₂_{_}_{M1} may flow through the second resistor R2. At node G, a first portion I₁_{_}_{M2} of reference current I_{REF}_{_}_{M2} may flow through the second BJT Q2, and a second portion I₂_{_}_{M2} may flow through the fourth resistor R4.

Reference current I_{REF}_{_}_{M3} may flow through the third resistor R3. A reference voltage V_{REF} may the voltage generated across the third resistor R3 with respect to the ground reference voltage V_{SS}. Assuming that the second and fourth resistors R2, R4 have the same resistance and that the reference currents I_{REF}_{_}_{M1}, I_{REF}_{_}_{M2}, I_{REF}_{_}_{M3} are equal in amount and denoted by I_{REF}, that amount may be mathematically represented as:

$${I}_{REF} = ( \frac{1}{{R}_{2}} ) [ {V}_{EB 2} + ( \frac{{R}_{2}}{{R}_{1}} ) ln ( N ) \cdot {V}_{T} ] ,$$

where R₁ represents the resistance of the first resistor R1, R₂ represents the resistance of the second and fourth resistors R2 and R4, V_{EB2} is the emitter-to-base voltage of the second BJT Q2, N represents a size ratio of the BJT channel width while length is the same, and V_{T} is the threshold voltage of the first and second BJTs Q2, Q2. As indicated by the equation, the amount of the reference current I_{REF} may depend on the resistances of the first and second resistors. Accordingly, as these resistance values change or due to PVT conditions, so will the amount of the reference current I_{REF}.

The gate terminals of the first, second, and third PMOS transistors M1, M2, M3 are tied together at node E. Referring back to FIGS. 1 and 2, the gate terminals of the PMOS transistors MP3 and MP4 are also connected to node E. As such, for configurations of the differential comparator systems 100, 200 that use the configuration 300 for its resistor-dependent current source 114, the gate terminals of the PMOS transistors MP3 and MP3 may be connected to the gate terminals of the PMOS transistors M1, M2, M3 of the example resistor-dependent current source 300. Accordingly, the first and second mirrored current I_{A} and I_{B} generated by the current mirror circuitry 116 may also depend on the resistances of the resistors R1 and R2 of the example resistor-dependent current source 300.

As previously described, whether the differential comparator circuit 102 outputs the output voltage V_{OUT} at one level or another to indicate presence or absence of a signal may depend on the first resistor voltage V_{AR}. However, the more the first resistor voltage V_{AR} varies, the less reliable the indication provided by the differential comparator 102 may be. As such, it may desirable for the first resistor voltage V_{RA} to be as stable as possible. The first and second resistor circuitries R_{A} and R_{B} may be subjected to various PVT conditions, including process and temperature as described above, that may cause their resistances to change during operation due to variations in temperature and/or differ from designed-for resistances due to resistance drift. However, by configuring the resistors R1, R2, R3, and R4 on the same chip and to be of the same type, the variations of the first and second resistor circuitries R_{A} and R_{B} due to PVT conditions may be offset by the resistors R1, R2, R3, and R4 being subjected to the same PVT conditions, which is manifested in the first and second mirrored currents I_{A} and I_{B} being supplied to the first and second resistor circuitries R_{A} and R_{B}, respectively, resulting in a stable first resistor voltage V_{RA}.

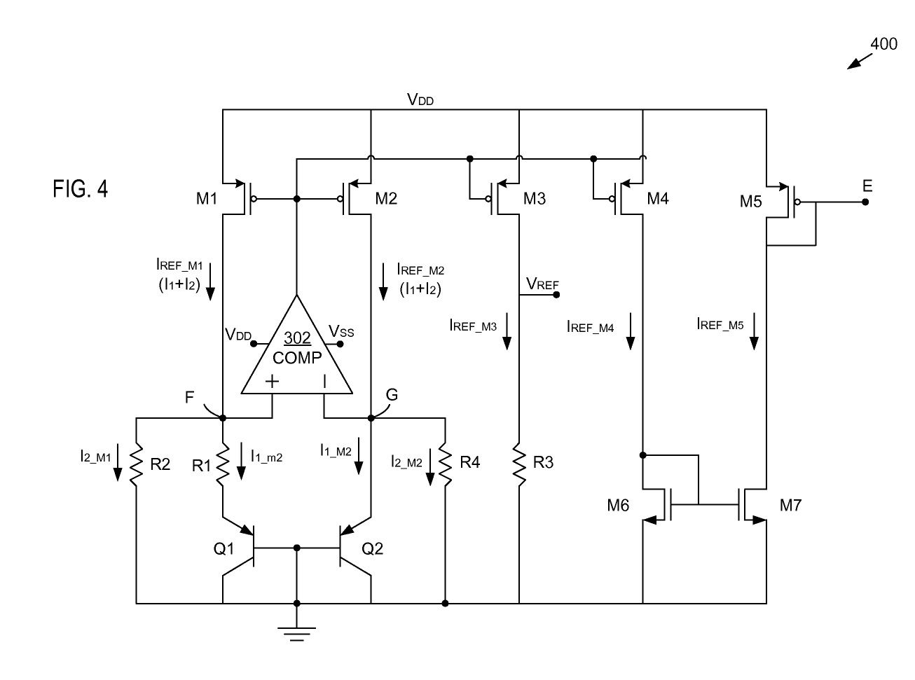

FIG. 4 is a block diagram of another example resistor-dependent current source 400, which may be used for the resistor-dependent current source 114 for either of the example differential comparator systems 100 or 200. The resistor-dependent current source 400 may be similar to the resistor-dependent current source 300 of FIG. 3, except that the resistor-dependent current source 400 may include additional current mirror circuitry to generate the reference current I_{REF}. The additional current mirror circuitry may include fourth and fifth PMOS transistors M4 and M5, and first and second NMOS transistors M6 and M6.

In further detail, a gate terminal of the fourth PMOS transistor may be tied to the gate terminals of the first, second, and third PMOS transistors M1, M2, and M3, which are connected to the output of the analog differential comparator 302. In addition, a source terminal of the fourth PMOS transistor M4 may be connected to the supply voltage V_{DD}, and a drain terminal of the fourth PMOS transistor M4 may be connected to a drain terminal of the first NMOS transistor M6. Source terminals of both the first and second NMOS transistors M6, M7 may be connected to the ground reference voltage V_{SS}. A drain terminal of the second NMOS transistor M7 may be connected to a drain terminal of the fifth PMOS transistor M5. A source terminal of the fifth PMOS transistor M5 may be connected to the supply voltage V_{DD}. Additionally, the gate terminal of the first NMOS transistor M6 may be connected to its drain terminal, and the gate terminal of the fifth PMOS transistor M5 may be connected to its drain terminal. As such, reference current I_{REF}_{_}_{M4} drawn through the fourth PMOS transistor M4 and the first NMOS transistor M6 and reference current I_{REF}_{_}_{M5} drawn through the fifth PMOS transistor M5 and the second NMOS transistor M7 may be mirrored versions of reference currents I_{REF}_{_}_{M1}, I_{REF}_{_}_{M2}, I_{REF}_{_}_{M3}.

As shown in FIG. 4, the gate terminal of the fifth PMOS transistor M5 is connected to node E. As such, when the example current-dependent current source 400 is used in the example differential comparator systems 100, 200, the first and second mirrored currents I_{A} and I_{B} may be mirrored versions of reference current I_{REF}_{_}_{M5}, the amount of which depends on the resistances R1 and R2. As such, for configurations of the example differential comparator systems 100, 200 that use the resistor-dependent current source 400, variations of the resistances of the first and second resistor circuitries R_{A} and R_{B} due to PVT conditions may be offset due to the first and second current mirrored currents I_{A} and I_{B} being dependent on the resistance R1 and R2.

The example resistor-dependent current sources 300 and 400 shown in FIGS. 3 and 4 respectively are merely exemplary and shown as non-limiting examples. Other resistor-dependent current sources that may include resistors of the same type and/or configured on the same chip or IC as the first and second resistor circuitries R_{A} and R_{B} may be used for the resistor-dependent current source 114 of FIG. 1 and/or FIG. 2.

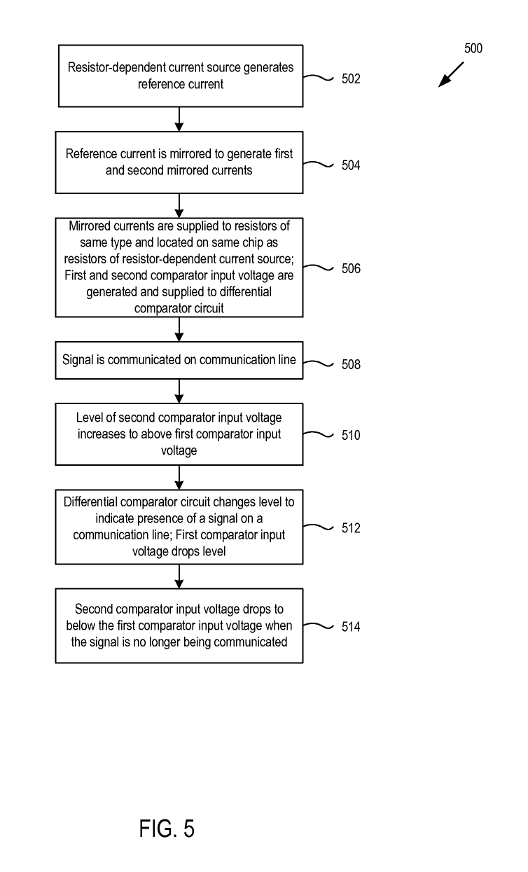

FIG. 5 shows a flow chart of an example method 500 of detecting presence of a signal on a communication line. At block 502, a reference current may be generated based on a resistance provided by one or more resistors of a resistor-dependent current source. At block 504, the reference current may be mirrored to generate first and second mirrored currents. At block 506, the first and second mirrored currents may be supplied to first and second resistors to respectively generate first and second comparator input voltages. The first and second comparator input voltage may be supplied to first and second input terminals of a differential comparator circuit. The first and second comparator input voltages may be generated such that when no signal is being communicated on the communication line, the first comparator input voltage is greater than the second comparator input voltage. In response, the different comparator circuit may output an output voltage at a level to indicate that no signal is being communicated on the communication line. In addition, the first and second resistors may be of the same type and located on the same chip as the one or more resistors of the resistor-dependent current source.

At block 508, a signal may be communicated on the communication line. At block 510, in response to the signal being communicated on the communication line, the level of the second comparator input voltage may increase to above the level of the first comparator input voltage. At block 512, in response to the level of the second comparator input voltage increasing above the level of the first comparator input voltage, the different comparator circuit may change the level of the output voltage to indicate that a signal is being communicated on the communication line. In addition, for some example methods, the output voltage may be fed back to a transistor connected in parallel with the first resistor to turn on the transistor. In response, the level of the first comparator input voltage may drop to a lower level. At block 514, the signal may no longer be communicated on the communication line, and in response, the level of the second comparator input voltage may drop to below the level of the first comparator input voltage. The differential comparator circuit may respond by switching the level of the output voltage back to the initial level to indicate that no signal is being communicated on the communication line.

One of skill in the art will recognize that this invention is not limited to the two dimensional and three dimensional exemplary structures described but cover all relevant memory structures within the spirit and scope of the invention as described herein and as understood by one of skill in the art.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the preferred embodiments described herein can be used alone or in combination with one another.

1. A comparator system comprising:
a comparator circuit configured to:
receive a first input voltage and a second input voltage; and
output an output voltage based on a difference between the first input voltage and the second input voltage;
an input circuit comprising first resistor circuitry, the input circuit configured to:
generate the first input voltage based on the first resistor circuitry; and
supply the first input voltage to the comparator circuit;
a resistor-dependent current generation circuit comprising:
a current source that comprises second resistor circuitry and transistor circuitry connected to an output of a comparator, the current source configured to generate a reference current that depends on the second resistor circuitry; and
current mirror circuitry forming a current mirror connection with the transistor circuitry, the current mirror circuitry configured to:
mirror the reference current to generate a resistor-dependent current that depends on the second resistor circuitry; and
supply the resistor-dependent current to the first resistor circuitry to generate the first input voltage,
wherein the first resistor circuitry and the second resistor circuitry are of the same type.

2. The comparator system of claim 1, wherein the input circuit and the resistor-dependent current generation circuit are configured on the same chip.

3. (canceled)

4. The comparator system of claim 1, wherein the input circuit comprises a first input circuit, wherein the resistor-dependent current comprises a first resistor-dependent current, and wherein the comparator system further comprises:
a second input circuit comprising third resistor circuitry, the second input circuit configured to generate the second input voltage and supply the second input voltage to the comparator circuit,
wherein the resistor-dependent current generation circuit is further configured to:
generate a second resistor-dependent current that depends on the second resistor circuitry; and
supply the second resistor-dependent current to the third resistor circuitry to generate the second input voltage,
wherein the third resistor circuitry is of the same type as the first and second resistor circuitries.

5. The comparator system of claim 4, wherein the second input circuit is configured on the same chip as the first input circuit and the resistor-dependent current generation circuitry.

6. The comparator system of claim 1, wherein the input circuit comprises a first input circuit, the comparator system further comprising a second input circuit configured to generate the second input voltage,
wherein the first input circuit is coupled to a first communication line and configured to generate the first input voltage based on a first line voltage on the first communication line,
wherein the second input circuit is coupled to a second communication line and configured to generate the second input voltage based on a second line voltage on the second communication line,
wherein the output voltage is indicative of a difference in voltage levels between the first line voltage and the second line voltage.

7. The comparator system of claim 6, wherein the first input circuit further comprises a first transistor connected in series with the first resistor circuitry and coupled to the first communication line,
wherein the second input circuit comprises third resistor circuitry connected in series with a second transistor, the second transistor coupled to the second communication line.

8. The comparator system of claim 1, further comprising:
a switch connected in parallel with the first resistor circuitry; and
a feedback connection coupling an output terminal of the comparator circuit with the switch,
wherein a level of the output voltage controls switching of the switch.

9. The comparator system of claim 8, wherein the comparator circuit is configured to output the output voltage such that the level of the output voltage opens the switch when the first input voltage exceeds the second input voltage and closes the switch when the second input voltage exceeds the first input voltage.

10. The comparator system of claim 1, wherein the first resistor circuitry and the second resistor circuitry have respective temperature coefficient parameters that are within 5% of each other.

11. The comparator system of claim 1, wherein the first resistor circuitry and the second resistor circuitry are both polysilicon resistors, P-POLY resistors saliside, P-POLY resistors non-saliside, N-POLY resistors saliside, N-POLY resistors non-saliside, Nwell resistors, or metal resistors.

12. A signal detection system comprising:
a signal detection circuit coupled to a pair of communication lines, the signal detection circuit comprising:
first resistor circuitry configured to generate an offset voltage;
a comparator circuit coupled to the first resistor circuitry, the comparator configured to generate an output voltage at a level that indicates whether a first line voltage on the pair of communication lines exceeds a second line voltage on the pair of communication lines by an amount corresponding to the offset voltage; and
a resistor-dependent current generation circuit comprising:
a current source that comprises second resistor circuitry and transistor circuitry connected to an output of a comparator, the current source configured to generate a reference current that depends on the second resistor circuitry; and
current mirror circuitry forming a current mirror connection with the transistor circuitry, the current mirror circuitry configured to:
mirror the reference current to generate a resistor-dependent current that depends on the second resistor circuitry; and
supply the resistor-dependent current to the first resistor circuitry to generate the first input voltage,
wherein the first resistor circuitry and the second resistor circuitry are of the same type.

13. The signal detection system of claim 12, wherein the first resistor circuitry and the second resistor circuitry are configured on the same chip.

14. The signal detection system of claim 12, further comprising:
a first input circuit that comprises the first resistor circuitry, the first input circuit configured to generate a first comparator input voltage to the comparator circuit, the first comparator input voltage based on the offset voltage and the first line voltage; and
a second input circuit that comprises third resistor circuitry, the second input circuit configured to generate a second comparator input voltage to the comparator circuit, the second input voltage based on the second line voltage.

15. The signal detection system of claim 14, wherein the resistor-dependent current comprises a first resistor-dependent current,
wherein the current mirror circuitry is further configured to:
mirror the reference current to generate a second resistor-dependent current that depends on the second resistor circuitry; and
supply the second resistor-dependent current to the third resistor circuitry.

16. The signal detection system of claim 14, wherein the second input circuitry is configured to generate the second comparator input voltage at a level that is greater than a level of the first comparator input voltage in response to the first line voltage and the second line voltage indicative of a presence of a differential signal on the pair of communication lines.

17. The signal detection system of claim 12, further comprising:
a switch connected in parallel with the first resistor circuitry; and
a feedback connection coupling an output terminal of the comparator circuit with the switch,
wherein a level of the output voltage controls switching of the switch.

18-20. (canceled)
